(19) United States
(12) Patent Application Publication
(10) Pub. No.: US 2023/0017865 A1
(43) Pub. Date: Jan. 19, 2023

(54) FULL COLOR MICROLED DISPLAY CONTROLLED BY NUMBER OF RED GREEN AND BLUE LEDS

(71) Applicant: GM GLOBAL TECHNOLOGY OPERATIONS LLC, Detroit, MI (US)

(72) Inventor: Jonglee Park, Troy, MI (US)

(21) Appl. No.: 17/376,366

(22) Filed: Jul. 15, 2021

(51) Int. Cl. G09G 3/32; H01L 25/075; H01L 33/58; B60K 35/00

(52) U.S. Cl. CPC G09G 3/32; H01L 25/0753; H01L 33/58; B60K 35/00; G09G 2380/10; G09G 2320/0242; G09G 2300/0452; B60K 2370/152; B60K 2370/188; B60K 2370/332; B60K 2370/46

(57) ABSTRACT

A system includes a display panel with several pixels. A pixel includes a first, a second, and a third set of light emitting diodes (LED). Each LED in the first set outputs a first color light, each LED in the second set outputs second color light, and each LED in the third set outputs a third color light. The pixel emits a display light of a color that is a combination of the first, second, and third colors. In response to a driver inputting a first electric current to the first set of LEDs, a second electric current to the second set, and a third electric current to the third set, the display light from the pixel is of a predetermined target color, the first, the second, and the third electric current being substantially same and within a predetermined tolerance of each other.

### INTRODUCTION

The present disclosure relates to display panels, and particularly systems, storage media and methods for a full color micro light emitting diode (LED) display controlled by number of red green and blue LEDs.

A microLED (also referred to as microLED, mLED or μLED, etc.) display panel includes several microscopic LEDs (called microLEDs). A microLED typically has a length of 50 micrometers or less. MicroLED display panels offer improved contrast, response times and energy efficiency compared to existing display panels, such as liquid crystal display (LCD) panels. Further, microLED display panels provide higher brightness, higher luminous efficacy, and longer lifespan than some other LED based display panels, such as organic LED (OLED).

### SUMMARY

According to one or more embodiments, a system includes a display panel that includes a plurality of pixels. A pixel includes a first set of light emitting diodes (LED), each LED in the first set of LEDs outputs a light of a first color. The pixel further includes a second set of LEDs, each LED in the second set of LEDs outputs a light of a second color. The pixel further includes a third set of LEDs, each LED in the third set of LEDs outputs a light of a third color. The pixel emits a display light of a color resulting from a combination of the light of the first color from the first set of LEDs, the light of the second color from the second set of LEDs, and light of the third color from the third set of LEDs. The display panel further includes a driver associated with the pixel, wherein the driver inputs an electric current to the pixel to control each of the first set of LEDs, the second set of LEDs, and the third set of the LEDs. In response to the driver inputting a first electric current to the first set of LEDs, a second electric current to the second set of LEDs, and a third electric current to the third set of LEDs, the display light from the pixel is of a predetermined target color, the first electric current, the second electric current, and the third electric current are substantially same and within a predetermined tolerance of each other.

In one or more examples, the predetermined target color is a result of a first predetermined number of LEDs in the first set of LEDs, a second predetermined number of LEDs in the second set of LEDs, and a third predetermined number of LEDs in the third set of LEDs.

In one or more examples, a brightness of the display light from the pixel of the predetermined target color is based on values of the first electric current, the second electric current, and the third electric current. The values of the first electric current, the second electric current, and the third electric current are based on an amount of ambient light surrounding the display panel.

In one or more examples, the first color is red, the second color is green, and the third color is blue.

In one or more examples, the display panel is part of a rearview assembly of a vehicle.

In one or more examples, the display panel is part of a vehicle.

According to one or more embodiments, a display device includes a driver circuit that provides an electric current to at least a first pixel from a plurality of pixels. The display panel further includes the plurality of pixels, wherein the first pixel includes a first predetermined number of red light emitting diodes (LEDs), a second predetermined number of green LEDs, and a third predetermined number of blue LEDs, wherein the first pixel emits a predetermined target color in response to a first electric current being applied to the red LEDs, a second electric current being applied to the green LEDs, and a third electric current being applied to the blue LEDs, the first electric current, the second electric current, and the third electric current being within a predetermined tolerance from each other.

In one or more examples, the display device further comprises a substrate, the plurality of pixels is disposed on the substrate.

In one or more examples, the driver circuit comprises a column drive circuit and a row drive circuit.

In one or more examples, the display device further includes a timing controller that provides timing signals to the driver circuit.

In one or more examples, a brightness of the predetermined target color is based on the first electric current, the second electric current, and the third electric current.

In one or more examples, the first pixel emits a display color based on the first electric current, the second electric current, and the third electric current not being with the predetermined tolerance from each other. A brightness of the display color is based on the first electric current applied to the red LEDs, the second electric current applied to the green LEDs, and the third electric current applied to the blue LEDs.

According to one or more embodiments, a vehicle includes a display panel that renders information from a processing circuit. The display panel includes a driver circuit that provides an electric current to at least a first pixel from a plurality of pixels. The display panel further includes the plurality of pixels, wherein the first pixel comprises a first predetermined number of red light emitting diodes (LEDs), a second predetermined number of green LEDs, and a third predetermined number of blue LEDs, wherein the first pixel emits a predetermined target color in response to a first electric current being applied to the red LEDs, a second electric current being applied to the green LEDs, and a third electric current being applied to the blue LEDs, the first electric current, the second electric current, and the third electric current being within a predetermined tolerance from each other.

In one or more examples, a brightness of the predetermined target color is based on the first electric current, the second electric current, and the third electric current.

In one or more examples, the first pixel emits a display color based on the first electric current, the second electric current, and the third electric current not being with the predetermined tolerance from each other.

In one or more examples, the display panel is an interior facing surface of the vehicle.

In one or more examples, the display panel is an exterior facing surface of the vehicle.

In one or more examples, the display panel is embedded in a transparent panel of the vehicle.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings.

FIG. 1 illustrates a top view of a microLED display panel 100 according to one or more examples;

FIG. 2 shows a cross-sectional view illustrated of a frontside illuminating microLED display panel according to one or more examples;

FIG. 3 depicts an example chart of a combination of red, green, and blue colors to generate a desired color;

FIG. 4 depicts examples where a display panel is used as part of a vehicle;

FIG. 5 depicts an example infotainment system with a display panel;

FIG. 6 shows an example view where the display panel is used as an exterior facing display in a vehicle; and

FIG. 7 depicts an example structure of using the display panel as part of a transparent display in a vehicle according to one or more examples.

### DETAILED DESCRIPTION

The following description is merely exemplary in nature and is not intended to limit the present disclosure, its application or uses. It should be understood that throughout the drawings, corresponding reference numerals indicate like or corresponding parts and features. As used herein, the term module refers to processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality.

Technical solutions described herein facilitate improvements to microLED display technology by providing a robust LED driving system for full color microLED display application by defining a number of each red, green and blue LEDs for each pixel so that the pixel produces a predetermined color (e.g., D65 target white illuminant) by applying a particular driving electric current value to each LED in the pixel. In other words, applying the (same) particular driving electric current value to each of the LEDs in the pixel causes the pixel to generate the predetermined color as output. The brightness of the output color is proportional to the value of the applied electric current in one or more examples.

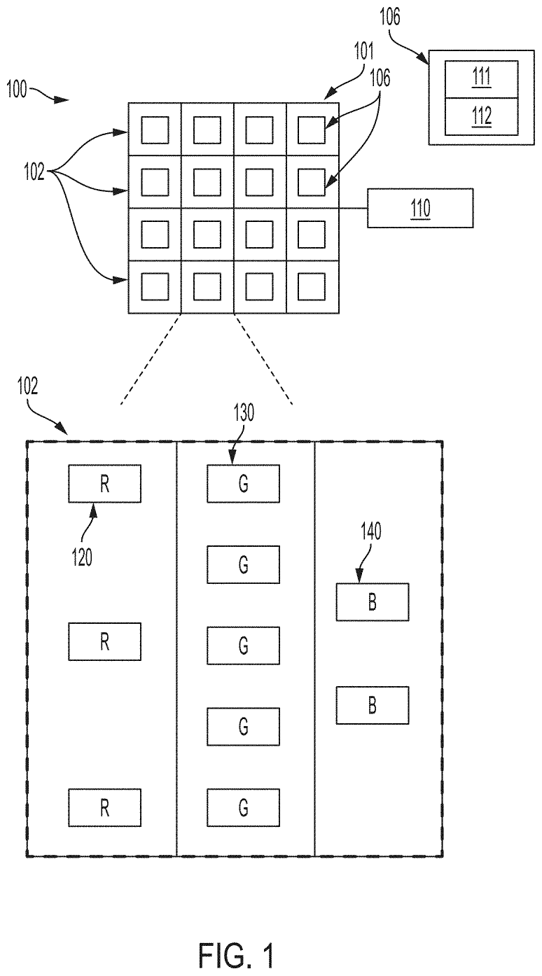

FIG. 1 illustrates a top view of a microLED display panel 100 according to one or more examples. The microLED display panel 100 includes a substrate 101 having microLEDs 120, 130, 140. The substrate 101 may be made of an insulating material (e.g., glass, Acrylic, etc.) or other materials suitable for supporting the microLEDs. A pixel 102 is a sub-region of the substrate 101.

An expanded view of a pixel 102 is also shown in FIG. 1. The pixel 102 includes one or more red microLEDs 120, one or more green microLEDs 130, and one or more blue microLEDs 140. Further, each pixel 102 is associated with a driver 106. It should be noted that although the example in FIG. 1 depicts a driver 106 for each respective pixel 102, in other examples, a driver 106 may be associated with a set of pixels 102 (two or more pixels). In yet other examples, each respective pixel 102 is associated with a set of drivers 106 (two or more drivers).

The driver 106 may be manufactured as an integrated circuit or chip. In some examples, the driver 106 is bonded on the surface of the pixel 102. The bonding can be performed using surface-mount technology (SMT) such as chip-on-glass (COG) or flip chip. In one or more examples, the drivers 106 and the microLEDs 120, 130, 140, are disposed on the same surface of the substrate 101.

In some examples, the microLED display panel 100 further includes a timing controller (TCON) 110. Some examples can include more than one TCON 110. The TCONs 110 are electrically connected with the substrate 101, for example, via a flexible printed circuit board (FPCB). The TCONs 110 are electrically connected with the drivers 106, for example, via signal traces (not shown) disposed on the substrate 101. The TCON 110 transmits timing control signals and data signals to the driver 106.

The driver(s) 106 provide(s) an electric current (driving current) to each microLED in each pixel 102 of the microLED display panel 100. The driver(s) 106 may use any driving method without affecting the technical features described herein. In some examples, the microLED display panel 100 uses a passive driving method for driving the microLEDs 120, 130, 140. In some examples, the driver 106 includes a column drive circuit 111 and/or a row drive circuit 112 (or scan drive circuit). The column drive circuit 111 transmits column drive signals to first electrodes (e.g., anodes) of the microLEDs 120, 130, 140 on the same columns, and the row drive circuit 112 transmits row drive signals to second electrodes (e.g., cathodes) of the microLEDs 120, 130, 140 on the same rows. The column drive circuit 111 and the row drive circuit 112 can be part of a single integrated circuit in some examples.

It is understood that the drawings are not to scale. The size range of the microLEDs 120, 130, 140, is between 1 and 10 micrometers. However, the size of the microLED may be even smaller due to specific applications or technological advance.

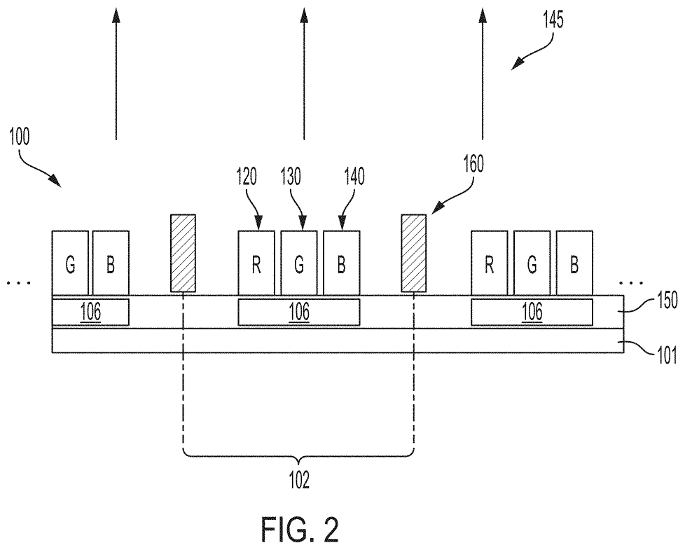

FIG. 2 shows a cross-sectional view illustrated of a frontside illuminating microLED display panel 100 according to one or more examples. In the depicted example, the microLEDs 120, 130, 140 and the driver 106 are disposed above a top surface of the substrate 101. Light 145 generated by the microLEDs 120, 130, 140 emits upward (i.e., frontside illuminating) from the top surface of the substrate 101 as indicated.

In some examples a trace layer 150 is disposed between a (e.g., top) surface of the substrate 101 and the microLEDs 120, 130, 140 and the driver 106. The trace layer 150 electrically connects the driver 106, the microLEDs 120, 130, 140 and the TCON 110 (FIG. 1).

In some examples a light blocking layer 160 is disposed between adjacent pixels 102. The light blocking layer 160 may be made of black matrix (BM) or other materials suitable for blocking light. In some examples, the light blocking layer is also disposed above the trace layer 150. Alternatively, or in addition, the light blocking layer 160 can be placed between each set of microLEDs 120, 130, 140 of the same pixels 102.

Each pixel 102 may include a set of red microLED 120, a set of green microLED 130, and a set of blue microLED 140. Each set can include one or more microLEDs of the same color.

It should be noted that the arrangement of the components depicted in FIG. 2 is exemplary, and that in other examples, the display panel 100 can include the same components arranged in a different manner. In yet other examples, the display panel 100 can include additional components. However, the technical features discussed herein are not substantially affected by such changes.

The technical features discussed herein address a technical challenge with robustness and flexibility of the display panel 100. The conventional full color display panels use additive color mixing using three primary color (red, green, and blue) to display a variety of display colors. Typically, a different level of lighting intensity from each LED is required to achieve a predetermined target color (e.g., D65 target white illuminant). Each red, green, and blue LEDs have a different lighting output features per driving current. The technical features described herein improve design robustness and flexibility of a microLED display panel 100 by having different numbers of each RGB LED per pixel 102 to drive each LED with substantially the same level of driving current value.

The technical solutions herein facilitate a display device having a full color microLED display panel 100. The display panel 100 includes a glass or film rear substrate (101) having a conductive layer (150) to provide electrical power to microLEDs 120, 130, 140 that form several pixels 102 on the display panel 100. Each pixel has a set of red microLEDs 120, a set of green microLEDs 130, and a set of blue microLEDs 140. The output of each set of microLEDs 120, 130, 140 mix to provide a display color. Based on the amount of light output by each red, green, and blue LED 120, 130, 140, the color of the display color changes. The similar level of driving current of each LEDs on a microLED display device; a glass film front substrate having a conductive layer to transfer electrical signals to each microLED group on the display pixel to create images by combining lighting from each pixel.

According to one or more aspects, the number of red microLEDs 120 in the set red microLEDs is a first predetermined number, the number of green microLEDs 130 is a second predetermined number, and the number of blue microLEDs 140 is a third predetermined number. The first, second, and third predetermined numbers of the respective red, green, and blue microLEDs in the pixel 102 are set to facilitate the pixel 102 to generate and emit a predetermined target display color (e.g., D65 white), when all the microLEDs are input the same electric current value concurrently. The display color of the pixel 102 depends on the light emitted by each set of the microLEDs, with the resulting display color being a combination of the red, green, and blue light emitted by the respective sets of microLEDs.

For example, if only red color is to be output, the blue and green microLEDs 130, 140 may be switched off (i.e., no (or less than a predetermined threshold level) electric current is applied to the blue and green microLEDs). In other instances, based on the color to be generated, different electric current values are applied to the respective sets of microLEDs 120, 130, 140 so that the amount of red, green, and blue light emitted combines to form the desired color.

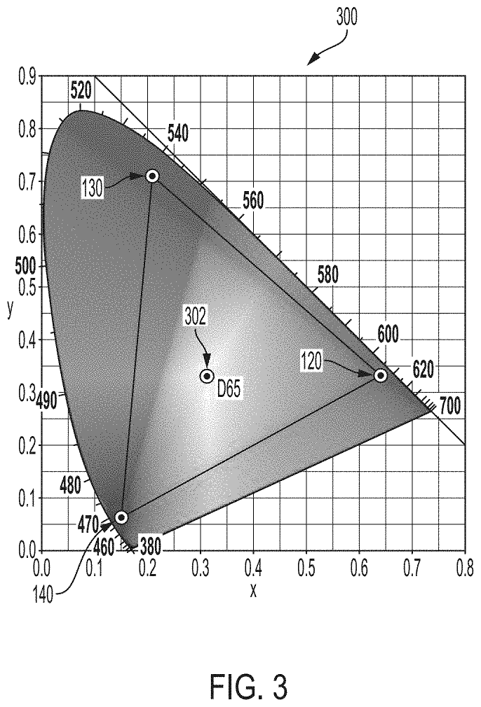

FIG. 3 depicts an example chart 300 of a combination of red, green, and blue colors to generate a desired color. The CIE 1931 color space chromaticity diagram, which uses a set of tristimulus values called X, Y, and Z, which are roughly red, green, and blue, respectively. A target display color 302 is depicted that is generated by combination of a proportion of the red, green, and blue light. It is understood that the target display color 302 can be different in different examples. Because the human eye has three types of color sensors that respond to different ranges of wavelengths, the chart 300 of all visible colors is a three-dimensional figure. As noted herein, the concept of color can be divided into two parts: brightness and chromaticity. For example, the color white is a bright color, while the color grey is considered to be a less bright version of that same white. In other words, the chromaticity of white and grey are the same while their brightness differs. The XYZ color space depicted in chart 300 is designed so that the Y parameter is a measure of the brightness or luminance of a color. The chromaticity of a color is then specified by the two derived parameters x and y, two of the three normalized values which are functions of all three tristimulus values X, Y, and Z. For example, in the CIE 1931 color space:

$$x = \frac{X}{X + Y + Z} \\ y = \frac{Y}{X + Y + Z} \\ z = \frac{Z}{X + Y + Z} = 1 - x - y$$

The derived color space specified by x, y, and Y is known as the CIE xyY color space and is widely used to specify colors in practice. It is understood that other color spaces can be used in one or more examples of the technical solutions described herein.

In an example, for the pixel 102, the first predetermined number of the red microLEDs 120 is fixed (e.g., R). Further, the second predetermined number of green microLEDs 130 is fixed (e.g., G). Subsequently, given an electric current value, E milliamperes, an amount of red light and an amount of green light emitted by the pixel 102 can be determined based on the first and second predetermined numbers. Further, using the chart 300, and given the amounts of red light and green light, the required amount of blue light to generate the target display color 302 can be computed. Subsequently, the number of blue microLEDs 140 required to generate the computed amount of blue light when applied the same electric current E milliamperes is computed. In other words, the current E milliamperes is common to all of the microLEDs of the pixel 102. The pixel 102 is accordingly configured to include the first predetermined number of red microLEDs 120, the second predetermined number of green microLEDs 130, and the number of blue microLEDs 140 as computed. It is understood that although R and G are fixed in the above example, in other examples, a different combination of microLEDs can be fixed. In some examples, the driver 106 can apply a first electric current to the first set of red microLEDs 120, a second electric current to the second set of green microLEDs 130, and a third electric current to the third set of blue microLEDs 140 to cause the display light from the pixel 102 to be of the predetermined target display color 302. The first electric current, the second electric current, and the third electric current are substantially same (e.g., E) but within a predetermined tolerance of each other (e.g., 1 milliamperes, 100 microamperes etc.). The technical solutions described herein, accordingly, reduce the driving current gap among different colors.

Along with the color (chroma) of the emitted light, the electric current(s) applied to the pixel 102 by the driver 106 also affect a brightness of the emitted light. In one or more aspects, the higher the value of the electric current that is commonly and concurrently applied to all of the microLEDs 120, 130, 140, the brighter is the emitted light of the pixel 102. For example, when an electric current value of X microamperes is applied to the set of red microLEDs 120, the set of green microLEDs 130, and the set of blue microLEDs 140, (i.e., all three sets of microLEDs) concurrently, the pixel 102 emits a light of the target display color 302 with brightness A nits; while an electric current value of Z microamperes applied to all three sets concurrently, causes the pixel to emit a light of the same target display color 302, but with brightness B nits. In one example, if Z>X, B>A.

In other words, a mixing ratio of the red, green, and blue light is determined for the target display color 302. The mixing ratio R:G:B=Rₘ:Gₘ:Bₘ. Further, for each of the microLEDs 120, 130, 140, lighting intensity ratio is determined per driving current. For example, lighting intensity ratio per driving current R:G:B=R_{L}:G_{L}:B_{L}. The number of microLEDs 120, 130, 140, per pixel is then calculated as: Number of microLED ratio per pixel

$$R : G : B = \frac{{R}_{m}}{{R}_{L}} : \frac{{G}_{m}}{{G}_{L}} : \frac{{B}_{m}}{{B}_{L}} .$$

Accordingly, by maintaining a predetermined tolerance among the three electric currents applied to the three types of microLEDs 120, 130, 140, the target display color 302 is achieved, and depending on the values of the electric currents, the brightness can vary. When the three electric currents are not within the predetermined tolerance, the display color may not be the predetermined target, and depends on the combination of the light 145 emitted by each of the microLEDs 120, 130, 140. In other words, when the three electric currents are not within a predetermined tolerance of each other, a different color is displayed by the pixel 102.

For example, in a first case, the red, green, and blue microLEDs 120, 130, 140 of the pixel 102 are applied currents E1, E2, E3, respectively. Consider that E1, E2, and E3 are within a predetermined tolerance of each other, say 0.5 milliamperes. The display color of the pixel 102 is the target display color 302. In a second case, the microLEDs 120, 130, 140 are applied currents E4, E5, E6, respectively. In this case too, E4, E5, E6, are within the same predetermined tolerance of each other. However, E4>E1, E5 >E2, and E6>E3. Here, the display color of the pixel 102 stays the same target display color 302, but with a different (e.g., higher) brightness than in the first case.

The predetermined numbers of the different types of the microLEDs per pixel facilitate a robust LED driving system by having a similar level of LED driving current to be used to generate the target display color 302.

In examples where the display panel 100 is used in high brightness areas, such as exteriors of vehicles, the predetermined numbers of the different types of the microLEDs 120, 130, 140, afford design flexibility to reach higher brightness display. In one or more examples, the display panel 100 can be used as a transparent display for an automobile, where the display panel 100 is embedded into layers of a windshield, side, or rear glass for either exterior or interior facing display.

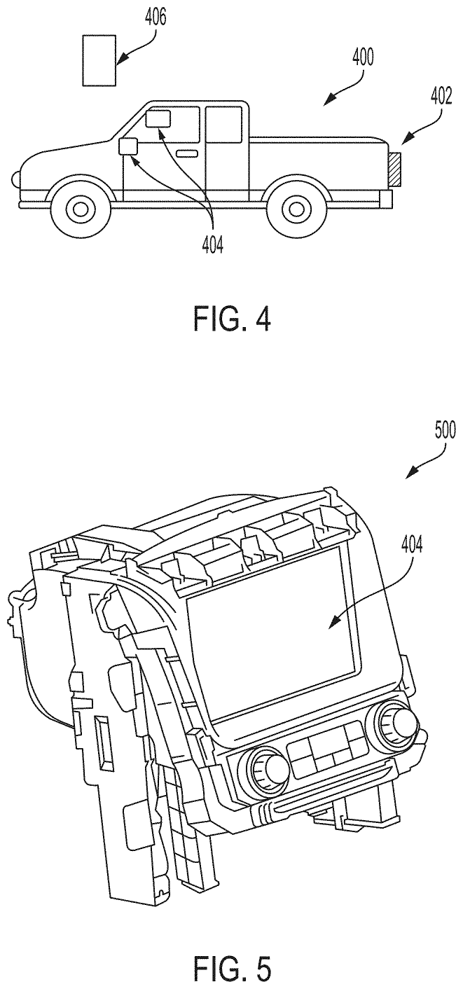

FIG. 4 depicts an example where the display panel is used as part of a vehicle 400. The display panel 100 can be used as part of a screen 404. The screen 404 can be inside the vehicle or on the exterior of the vehicle, or both. The screen 404 can refer to multiple display panels 100 that the vehicle 400 is equipped with. The screen 404 renders information to one or more users, such as the occupants of the vehicle 400. For example, the screen 404 can be part of an infotainment system. FIG. 5 depicts an example infotainment system 500 that includes the screen 404. The screen 404 of the infotainment system 500 can be used to display information such as radio channels, vehicle metrics (e.g., odometer, time, etc.), navigation data, games, video, clock, etc.

In addition, the screen 404 displays information captured by one or more sensors 402 equipped on the vehicle 400. For example, the sensors 402 can include radar, lidar, camera, ambient light sensor, or any other such sensor device. The data measured using the sensors 402 is used to render information on the display panel 100. In one example, a camera captures a scene in the rear of the vehicle 400, and the scene is rendered on the screen 404. The screen 404, in this manner, can be used as part of a rearview assembly in lieu of (or in addition to) a rearview mirror. It is understood that scenes from other sides of the vehicle 400 can also be rendered in other examples. Alternatively, or in addition, the screen 400 can be used to render information from other types of sensors 402 that are equipped on the vehicle 400. The screen communicates with the sensors 402 in a wired and/or wireless manner. Alternatively, or in addition, the screen 404 can be used to mirror or render information from a user equipment 406, such as a phone, a wearable, a laptop, a tablet computer, etc. In one or more examples, the screen 404 can also be part of a separation screen between a front portion (e.g., driver's seat) and a rear portion (passenger's seat) of the vehicle 400. The screen communicates with the user equipment 406 in a wireless and/or a wired manner.

In one or more examples, a light sensor detects an amount of ambient light surrounding the display panel 100. Based on the amount of ambient light, a brightness of the light to be emitted by the pixels 102 of the display panel 100 is determined. The brightness can be specified so that information rendered by the display panel 100, (i.e., the light emitted by the display panel 100), is visible to the one or more users. Alternatively, the brightness of the display panel 100 can be configured based on a time of day, for example, higher brightness during daytime, and a lower brightness during the nighttime. In other examples, the brightness of the display panel 100 can be manually set by one or more users. Based on the desired brightness of the light, the common electric current value that is applied to the microLEDs 120, 130, 140, of the pixels 102 to generate the target display color 302 is determined.

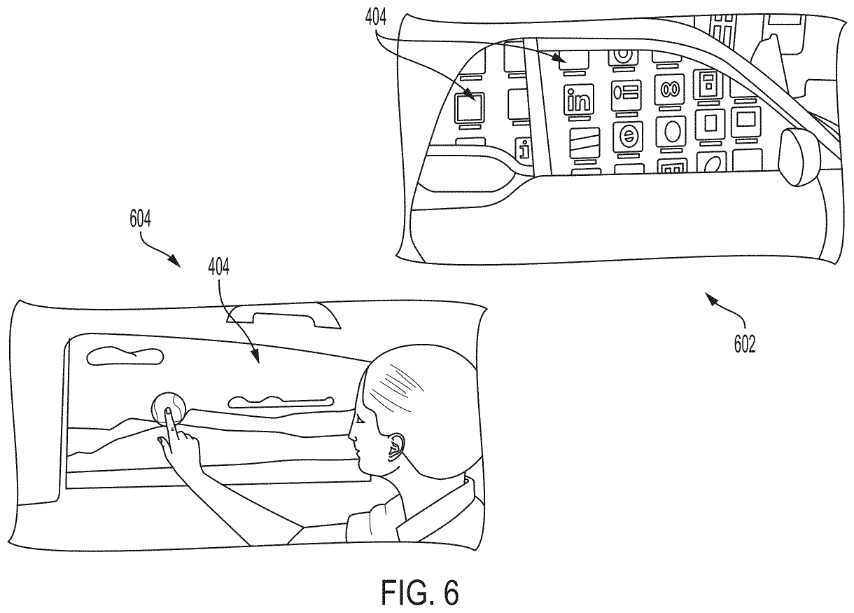

FIG. 6 shows an example view 602 where the display panel 404 is used as an exterior facing display in the vehicle 400. Further, example view 604 shows the display panel 100 being used as an interior facing display in the vehicle 400.

It is understood that the vehicle 400 is exemplary, and that the technical features described herein are applicable in other types of vehicles than the one depicted. Additionally, it is understood that the positions of the sensors 402 and the screen 404 is exemplary, and that in other examples, the positions, shapes, sizes of such components can vary.

It is further understood that although some possible uses of the display panel 100 in a vehicle 400 are described herein, the display panel 100 is not limited to only such uses. The display panel 100 can be used in various other cases where a display device is required, such as wearables, phones, computers, televisions, monitors, appliances, or any other electronic device that includes and/or uses a display to render information to one or more users.

The technical solutions described herein provide a device that provides a robust LED driving system for full color microLED display application by defining a number of each red, green, and blue LEDs for each pixel so that a mixed color at a certain level of driving current for each LED produces a predetermined target illuminant (e.g., D65). In addition to various advantages of the technical solutions described herein, the technical features also facilitate a cost saving by reducing number of LEDs that has higher lighting efficiency than other LEDs. For the microLED display that is wholly controlled by driving current, the same amount of microLEDs for each R 120, G 130 and B 140 can be used to provide a higher brightness (without increasing number of microLEDs). Technical solutions herein accordingly facilitate a cost saving by optimizing number of LEDs for higher brightness display.

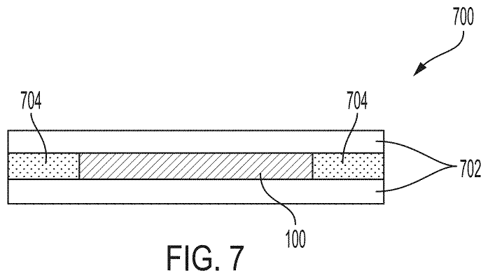

FIG. 7 depicts an example structure of using the display panel as part of a transparent display/screen in the vehicle 400 according to one or more examples. The display panel 100 is embedded between other material used to manufacture a transparent panel 700. The transparent panel 700 can be used as part of the windows, windshield, etc. of the vehicle 400. For example, a pair of glass sheets 702 can encompass the display panel 100. In some examples, the glass sheets 702 are transparent so that a user can view the light emitted by the display panel. In some examples, the glass sheets 702 are touch sensitive to facilitate the user to interact with the display panel 100.

In some examples, other material such as insulation 704 can be embedded in the transparent panel 700. It is understood that in other examples, the transparent panel 700 can include other material embedded in it.

While the above disclosure has been described with reference to exemplary embodiments, it will be understood by those skilled in the art that various changes may be made, and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope of the application.

1. A system comprising:
a display panel comprising a plurality of pixels, wherein a pixel comprises:
a first set of light emitting diodes (LED), each LED in the first set of LEDs outputs a light of a first color;
a second set of LEDs, each LED in the second set of LEDs outputs a light of a second color; and
a third set of LEDs, each LED in the third set of LEDs outputs a light of a third color; and
wherein, the pixel is configured to emit a display light of a predetermined target color resulting from a combination of the light of the first color from the first set of LEDs, the light of the second color from the second set of LEDs, and light of the third color from the third set of LEDs;
a driver associated with the pixel, wherein the driver inputs an electric current to the pixel to control each of the first set of LEDs, the second set of LEDs, and the third set of LEDs; and
wherein in response to the driver inputting the electric current to each of the first set of LEDs, the second set of LEDs, and the third set of LEDs, to cause the display light from the pixel to be of the predetermined target color, computing a number of LEDs to use from the third set of LEDs based on a predetermined number of LEDs to be used from the first set of LEDs and the second set of LEDs, and the electric current.

2. The system of claim 1, wherein the predetermined target color is a result of a first predetermined number of LEDs in the first set of LEDs, a second predetermined number of LEDs in the second set of LEDs, and the number of LEDs from the third set of LEDs.

3. The system of claim 1, wherein a brightness of the display light from the pixel of the predetermined target color is based on the electric current.

4. The system of claim 3, wherein electric current is based on an amount of ambient light surrounding the display panel.

5. The system of claim 1, wherein the first color is red, the second color is green, and the third color is blue.

6. The system of claim 1, wherein the display panel is part of a rearview assembly of a vehicle.

7. The system of claim 1, wherein the display panel is part of a vehicle.

8. A display device comprising:
a driver circuit that provides an electric current to at least a first pixel from a plurality of pixels; and
the plurality of pixels, wherein the first pixel comprises a first predetermined number of first color light emitting diodes (LEDs), a second predetermined number of second color LEDs, and a third predetermined number of third color LEDs, wherein the first pixel emits a predetermined target color in response to the electric current being applied to the red LEDs, by computing a number of the third color LEDs to use based on the first predetermined number, the second predetermined number of second color LEDs, and the electric current.

9. The display device of claim 8, wherein the display device further comprises a substrate, and the plurality of pixels is disposed on the substrate.

10. The display device of claim 8, wherein, the driver circuit comprises a column drive circuit and a row drive circuit.

11. The display device of claim 8, further comprising a timing controller that provides timing signals to the driver circuit.

12. The display device of claim 8, wherein a brightness of the predetermined target color is based on the electric current and the first predetermined number of the first color LEDs, the second predetermined number of the second color LEDs, and the number of the third color LEDs.

13. The display device of claim 8, wherein the first pixel emits a display color, distinct from the predetermined target color, in response to the first color LEDs, the second color LEDs, and the third color LEDs being applied electric currents that are distinct from each other.

14. The display device of claim 13, wherein a brightness of the display color is based on the number of the third color LEDs.

15. A vehicle comprising:
a display panel that renders information from a processing circuit, the display panel comprising:
a driver circuit that provides an electric current to at least a first pixel from a plurality of pixels; and
the plurality of pixels, wherein the first pixel comprises a first predetermined number of first color light emitting diodes (LEDs), a second predetermined number of second color LEDs, and a third predetermined number of third color LEDs, wherein the first pixel emits a predetermined target color in response to the electric current being applied to the red LEDs, by computing a number of the third color LEDs to use based on the first predetermined number, the second predetermined number of second color LEDs, and the electric current.

16. The vehicle of claim 15, wherein a brightness of the predetermined target color is based on the first predetermined number, the second predetermined number, and the number of the third color LEDs that is computed.

17. The vehicle of claim 15, wherein the first pixel emits a display color, distinct from the predetermined target color, in response to the first color LEDs, the second color LEDs, and the third color LEDs being applied electric currents that are distinct from each other.

18. The vehicle of claim 15, wherein the display panel is an interior facing surface of the vehicle.

19. The vehicle of claim 15, wherein the display panel is an exterior facing surface of the vehicle.

20. The vehicle of claim 15, wherein the display panel is embedded in a transparent panel of the vehicle.
